(19) United States
(12) Patent Application Publication
(10) Pub. No.: US 2025/0226329 A1
(43) Pub. Date: Jul. 10, 2025

(54) CHIP PACKAGE STRUCTURE AND MANUFACTURING METHOD THEREOF

(71) Applicant: Chung W. Ho, Taipei City (TW)

(72) Inventor: Chung W. Ho, Taipei City (TW)

(21) Appl. No.: 18/748,036

(22) Filed: Jun. 19, 2024

(30) Foreign Application Priority Data
Jan. 5, 2024 (TW) 113100572

(51) Int. Cl. H01L 23/538; H01L 23/00; H01L 23/498; H01L 25/065

(52) U.S. Cl. CPC H01L 23/5386; H01L 23/5383; H01L 23/49816; H01L 24/16; H01L 25/0655

(57) ABSTRACT

A chip package structure includes a multi-layer circuit layer and at least one chip. The multi-layer circuit layer has a first surface and a second surface opposite to each other, and includes a high-density circuit layer, a medium-density circuit layer and a low-density circuit layer. The high-density circuit layer has a first surface. The medium-density circuit layer is located between the high-density circuit layer and the low-density circuit layer. The low-density circuit layer has a second surface. The high-density circuit layer has a first line width, the medium-density circuit layer has a second line width, and the low-density circuit layer has a third line width. The first line width is less than the second line width, and the second line width is less than the third line width. The chip is disposed on the first surface of the high-density circuit layer and is electrically connected to the multi-layer circuit layer.

### CROSS-REFERENCE TO RELATED APPLICATION

This application claims the priority benefit of Taiwan application serial no. 113100572, filed on Jan. 5, 2024. The entirety of the above-mentioned patent application is hereby incorporated by reference herein and made a part of specification.

### BACKGROUND

### Technical Field

The invention relates to a package structure and a manufacturing method thereof, and particularly relates to a chip package structure and a manufacturing method thereof.

### Description of Related Art

In the existing chip package structure, the chip is electrically connected to fine circuits on the package substrate. For the package substrate, fine circuits and coarse circuits are usually made separately first, and then the fine circuits and the coarse circuits are structurally and electrically connected by using solder balls. In this way, the production time cannot be further shortened due to the need to assemble the fine circuits and the coarse circuits, and since additional solder balls are required to connect the fine circuits and the coarse circuits, not only material cost is increased, but also additional vertical space in the overall package structure is occupied, resulting in yield and performance losses.

### SUMMARY

The invention is directed to a chip package structure and a manufacturing method thereof, which do not require assembly and effectively save man-hours and material costs.

The invention provides a chip package structure including a multi-layer circuit layer and at least one chip. The multi-layer circuit layer has a first surface and a second surface opposite to each other, and includes a high-density circuit layer, a medium-density circuit layer and a low-density circuit layer. The high-density circuit layer has a first surface. The medium-density circuit layer is located between the high-density circuit layer and the low-density circuit layer. The low-density circuit layer has a second surface. The high-density circuit layer has a first line width, the medium-density circuit layer has a second line width, and the low-density circuit layer has a third line width. The first line width is less than the second line width, and the second line width is less than the third line width. The chip is disposed on the first surface of the high-density circuit layer and is electrically connected to the multi-layer circuit layer.

In an embodiment of the invention, the chip package structure further includes a multi-layer power board disposed on the second surface of the multi-layer circuit layer of the second-layer structure with a high coefficient of thermal expansion. The multi-layer power board is a circuit substrate with few or no traces and is composed of thick copper and insulating materials with high thickness and very low coefficient of thermal expansion. The multi-layer power board has a plurality of conductive vias. The conductive vias are electrically connected to the multi-layer circuit layer to achieve power supply transmission. The three group structure corresponds to the first group structure of the chip, which has a low coefficient of thermal expansion, the second group of circuit layers of high coefficient of thermal expansion and the third group is the multilayer power group of low coefficient of thermal expansion. The three groups therefore maintain a stable balance effect even in a range of a temperature difference change. A first peripheral surface of the multi-layer circuit layer is aligned with a second peripheral surface of the multi-layer power board.

In an embodiment of the invention, the chip package structure further includes a support plate disposed on the first surface of the multi-layer circuit layer. The support plate has at least one opening, and the chip is disposed in the opening.

In an embodiment of the invention, a material of the support plate includes copper, stainless steel or alloy.

In an embodiment of the invention, a number of layers of the high-density circuit layer ranges from 2 layers to 10 layers, and a line width and line spacing of the high-density circuit layer range from 2 μm to 4 μm.

In an embodiment of the invention, a number of layers of the medium-density circuit layer ranges from 2 layers to 15 layers, and a line width and line spacing of the medium-density circuit layer range from 5 μm to 10 μm.

In an embodiment of the invention, a number of layers of the low-density circuit layer ranges from 0 to 20 layers, and a line width of the low-density circuit layer ranges from 10 μm to 20 μm.

The invention provides a manufacturing method of a chip package structure, which includes following steps. A multi-layer circuit layer is formed on a substrate. The multi-layer circuit layer has a first surface and a second surface opposite to each other, and includes a high-density circuit layer, a medium-density circuit layer and a low-density circuit layer. The high-density circuit layer has a first surface. The medium-density circuit layer is located between the high-density circuit layer and the low-density circuit layer. The low-density circuit layer has a second surface. The high-density circuit layer has a first line width, the medium-density circuit layer has a second line width, and the low-density circuit layer has a third line width. The first line width is less than the second line width, and the second line width is less than the third line width. The first surface of the multi-layer circuit layer is disposed on the substrate. The substrate is removed to expose the first surface of the multi-layer circuit layer. At least one chip is disposed on the first surface of the high-density circuit layer. The chip is electrically connected to the multi-layer circuit layer.

In an embodiment of the invention, the manufacturing method of the chip package structure further includes forming a multi-layer power board on the second surface of the multi-layer circuit layer of a second-layer structure with a high coefficient of thermal expansion before removing the substrate to expose the first surface of the multi-layer circuit layer. The multilayer power board is a circuit substrate with few or no traces and is composed of thick copper and insulating materials with high thickness and very low coefficient of thermal expansion, and the multi-layer power board has a plurality of conductive vias. The conductive vias are electrically connected to the multi-layer circuit layer to achieve power supply transmission. The three group structure corresponds to the first group structure of the chip, which has a low coefficient of thermal expansion, the second group of circuit layers of high coefficient of thermal expansion and the third group is the multi-layer power group of low coefficient of thermal expansion. The three groups therefore maintains a stable balance effect even in a range of a temperature difference change. A first peripheral surface of the multi-layer circuit layer is aligned with a second peripheral surface of the multi-layer power board.

In an embodiment of the invention, the above-mentioned manufacturing method of the chip packaging structure further includes disposing at least one chip on the first surface of the high-density circuit layer, disposing a support plate on the first surface of the multi-layer circuit layer. The support plate has at least one opening, and the chip is disposed in the opening.

Based on the above description, in the chip package structure of the invention, the multi-layer circuit layer with multiple line widths is used to replace the fine circuits and coarse circuits assembled with solder balls in the prior art, thereby eliminating the need for assembly and effectively saving man-hours and material costs.

To make the aforementioned more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1C are schematic cross-sectional views of a manufacturing method of a chip package structure according to an embodiment of the invention.

FIG. 2A to FIG. 2B are schematic cross-sectional views of partial steps of a manufacturing method of a chip package structure according to another embodiment of the invention.

FIG. 3A to FIG. 3B are schematic cross-sectional views of partial steps of a manufacturing method of a chip package structure according to another embodiment of the invention.

### DESCRIPTION OF THE EMBODIMENTS

The embodiments of the invention may be understood with reference of the drawings, and the drawings of the invention are also regarded as part of the disclosure description. It is to be understood that the drawings of the invention are not drawn to scale and, in fact, dimensions of elements may be arbitrarily exaggerated or reduced in order to clearly illustrate the features of the invention.

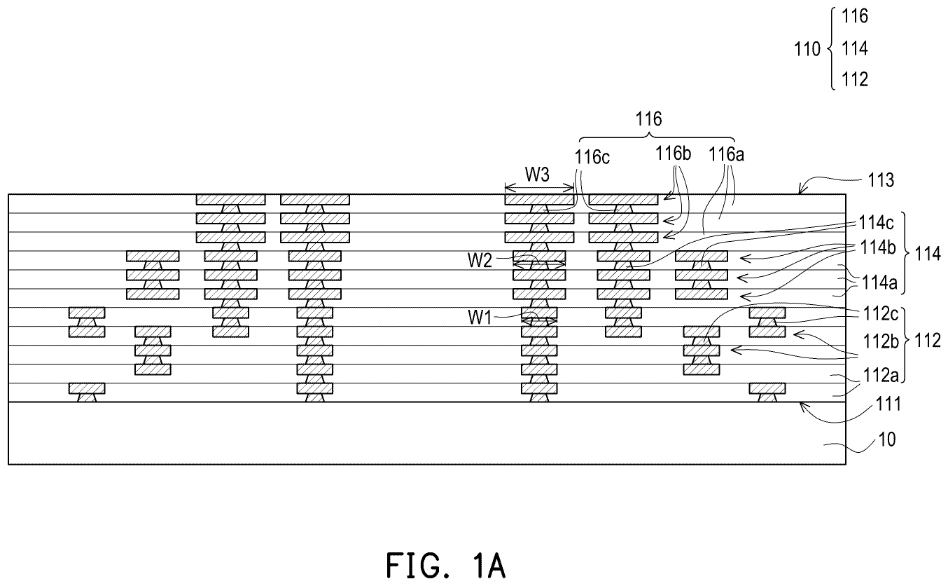

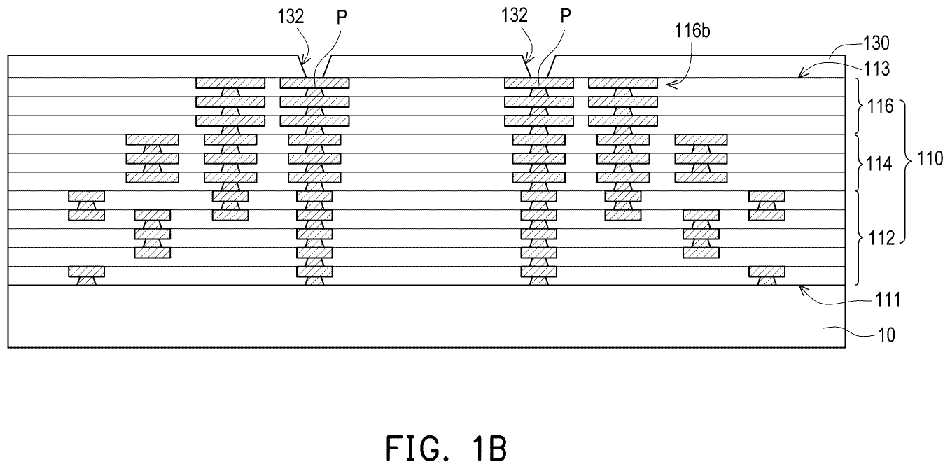

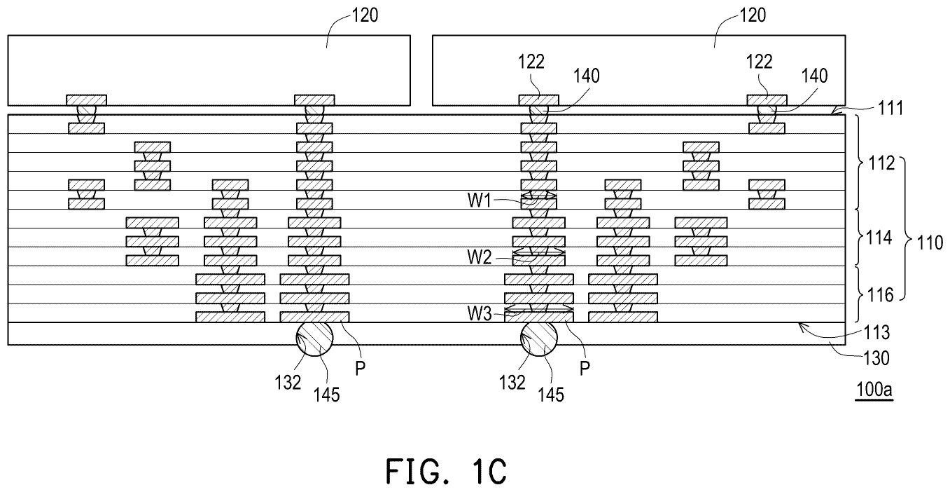

FIG. 1A to FIG. 1C are schematic cross-sectional views of a manufacturing method of a chip package structure according to an embodiment of the invention. Regarding the manufacturing method of the chip package structure of the embodiment, first, referring to FIG. 1A, a multi-layer circuit layer 110 is formed on a substrate 10. The multi-layer circuit layer 110 has a first surface 111 and a second surface 113 opposite to each other, and includes a high-density circuit layer 112, a medium-density circuit layer 114 and a low-density circuit layer 116. The high-density wiring layer 112 has the first surface 111. The medium-density circuit layer 114 is located between the high-density circuit layer 112 and the low-density circuit layer 116. The low-density circuit layer 116 has the second surface 113. The high-density circuit layer 112 has a first line width W1, the medium-density circuit layer 114 has a second line width W2, and the low-density circuit layer 116 has a third line width W3. The first line width W1 is less than the second line width W2, and the second line width W2 is less than the third line width W3. The first surface 111 of the multi-layer circuit layer 110 is disposed on the substrate 10.

In an embodiment, the substrate 10 is, for example, a glass substrate, a prepreg (PP) substrate, a stainless steel substrate, or other smooth substrate with support, but the invention is not limited thereto. In an embodiment, a number of layers of the high-density circuit layer 112 is, for example, between 2 layers and 10 layers, and a line width and line spacing of the high-density circuit layer 112 is, for example, between 2 μm and 4 μm. Furthermore, the high-density circuit layer 112 may include a multi-layer dielectric layer 112a, a multi-layer patterned circuit layer 112b and a plurality of conductive blind vias 112c. The dielectric layer 112a and the patterned circuit layer 112b are arranged in interleaving, and the conductive blind vias 112c electrically connect two adjacent patterned circuit layers 112b. In an embodiment, a material of the dielectric layer 112a is, for example, polyimide (PI), Ajinomoto build-up film (ABF) or benzocyclobutene (BCB), but the invention is not limited thereto. A material of the patterned circuit layer 112b and the conductive blind via 112c may be, for example, copper, but the invention is not limited thereto.

In an embodiment, a number of layers of the medium-density circuit layer 114 is, for example, between 2 layers and 15 layers, and a line width and line spacing of the medium-density circuit layer 114 is, for example, between 5 μm and 10 μm. Furthermore, the medium-density circuit layer 114 may include a multi-layer dielectric layer 114a, a multi-layer patterned circuit layer 114b and a plurality of conductive blind vias 114c. The dielectric layer 114a and the patterned circuit layer 114b are arranged in interleaving, and the conductive blind vias 114c electrically connect two adjacent patterned circuit layers 114b. In an embodiment, a material of the dielectric layer 114a is, for example, polyimide (PI), Ajinomoto build-up film (ABF) or pre-preg (PP), but the invention is not limited thereto. A material of the patterned circuit layer 114b and the conductive blind via 114c may be, for example, copper, but the invention is not limited thereto.

In an embodiment, a number of layers of the low-density circuit layer 116 is, for example, between 0 and 20 layers, and a line width of the low-density circuit layer 116 is, for example, between 10 μm and 20 μm. Furthermore, the low-density circuit layer 116 may include a multi-layer dielectric layer 116a, a multi-layer patterned circuit layer 116b and a plurality of conductive blind vias 116c. The dielectric layer 116a and the patterned circuit layer 116b are arranged in interleaving, and the conductive blind vias 116c electrically connect two adjacent patterned circuit layers 116b. In an embodiment, when the low-density circuit layer 116 is not needed, the number of layers thereof may be 0. In an embodiment, a material of the dielectric layer 116a is, for example, polyimide (PI), Ajinomoto build-up film (ABF) or pre-preg (PP), but the invention is not limited thereto. A material of the patterned circuit layer 116b and the conductive blind via 116c may be, for example, copper, but the invention is not limited thereto.

In fabrication, the high-density circuit layer 112 in the multi-layer circuit layer 110 may be formed on a smooth mirror plate by coating or laminating. Then, the medium-density circuit layer 114 and the low-density circuit layer 116 may be sequentially formed on the high-density circuit layer 112 by, for example, laminating, to complete the fabrication of the multi-layer circuit layer 110. Then, the multi-layer circuit layer 110 may be transferred to a support substrate. It is relatively easier to start with the high-density circuit layer 112, and after transferring the board, the high-density circuit layer 112 is used as required for the application.

In brief, the multi-layer circuit layer 110 of the embodiment is composed of circuit structure layers with a variety of different densities, line widths and line width and line spacings. and the circuit layers of different densities are in direct contact without any need for solder balls, so that there is no need for assembly, which effectively saves man-hours and material costs.

Then, referring to FIG. 1B, a solder mask layer 130 is formed on the multi-layer circuit layer 110, where the solder mask layer 130 has a plurality of solder mask openings 132, and the solder mask openings 132 expose a part of the patterned circuit layer 116b of the low-density circuit layer 116 to define a plurality of pads P.

Then, referring to FIG. 1B and FIG. 1C at the same time, the substrate 10 is removed to expose the first surface 111 of the multi-layer circuit layer 110.

Finally, referring to FIG. 1C again, at least one chip (two chips 120 are schematically shown) is disposed on the first surface 111 of the high-density circuit layer 112, where chip pads 122 of the chip 120 are electrically connected to the multi-layer circuit layer 110 through solder balls 140. In an embodiment, the chip 120 may be, for example, a single chip or a multi-chip, where the chip 120 is electrically connected to the multi-layer circuit layer 110 in a flip-chip manner. In addition, in order to be electrically connected to an external circuit, a solder ball 145 may be formed on a pad P. and the pad P may be electrically connected to an external circuit through the solder ball 145. At this point, fabrication of a chip package structure 100a is completed.

In terms of structure, referring to FIG. 1C again, the chip package structure 100a includes the multi-layer circuit layer 110 and the chip 120. The multi-layer circuit layer 110 has the first surface 111 and the second surface 113 opposite to each other, and includes the high-density circuit layer 112, the medium-density circuit layer 114 and the low-density circuit layer 116. The high-density wiring layer 112 has the first surface 111. The medium-density circuit layer 114 is located between the high-density circuit layer 112 and the low-density circuit layer 116. The low-density circuit layer 116 has the second surface 113. The high-density circuit layer 112 has the first line width W1, the medium-density circuit layer 114 has the second line width W2, and the low-density circuit layer 116 has the third line width W3. The first line width W1 is less than the second line width W2, and the second line width W2 is less than the third line width W3. The chip 120 is disposed on the first surface 111 of the high-density circuit layer 112 and is electrically connected to the multi-layer circuit layer 110.

In brief, the chip package structure 100a of the embodiment uses the multi-layer circuit layer 110 with various line widths to replace the fine circuits and coarse circuits assembled with solder balls in the prior art, thereby eliminating the need for assembly and effectively saving man-hours and material costs. In addition, since there is no need to assemble through solder balls, a vertical space of the overall package structure may be saved, which may effectively improve yield and performance.

It should be noticed that reference numbers of the components and a part of contents of the aforementioned embodiment are also used in the following embodiment, where the same reference numbers denote the same or like components, and descriptions of the same technical contents are omitted. The aforementioned embodiment may be referred for descriptions of the omitted parts, and detailed descriptions thereof are not repeated in the following embodiment.

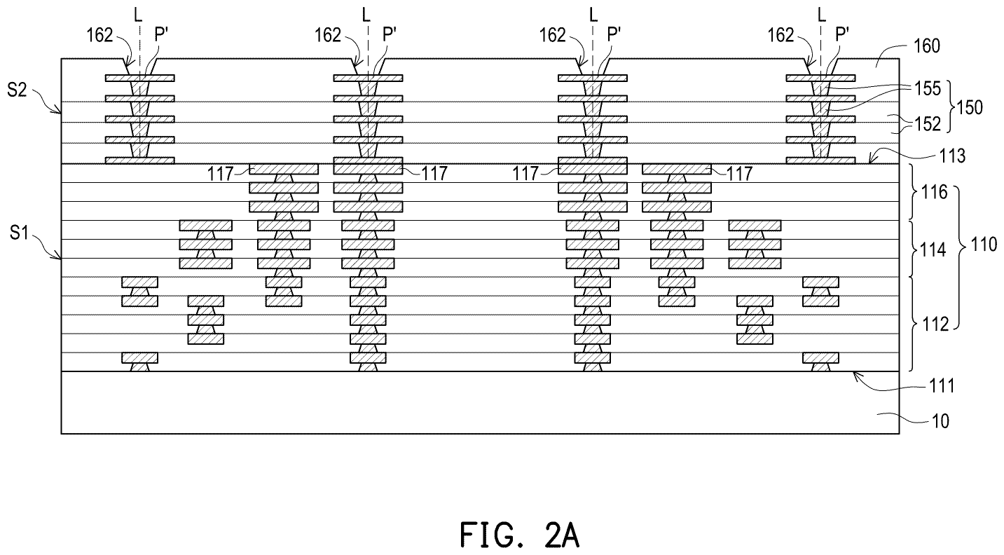

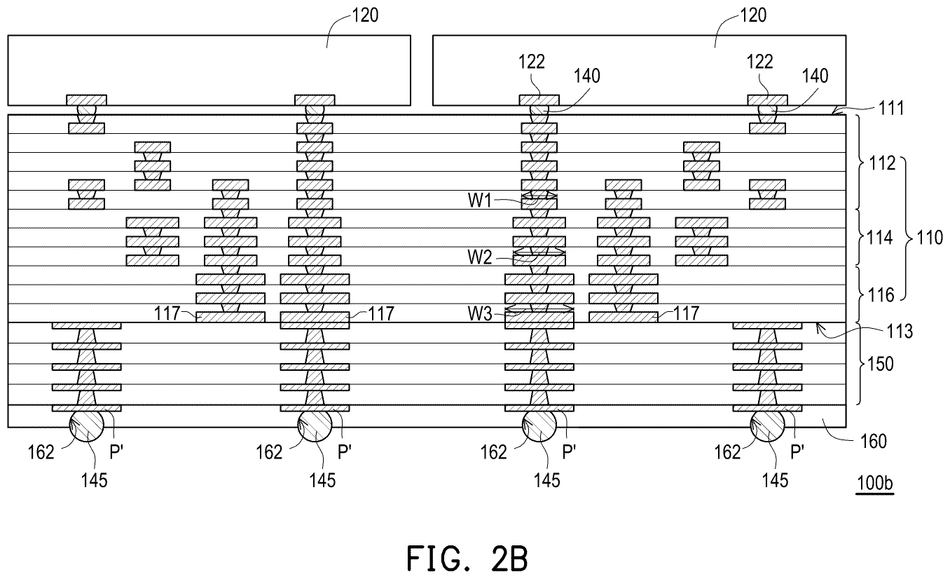

FIG. 2A to FIG. 2B are schematic cross-sectional views of partial steps of a manufacturing method of a chip package structure according to another embodiment of the invention. Referring to FIG. 1B and FIG. 2A at the same time, the manufacturing method of the chip package structure of the embodiment is similar to the aforementioned manufacturing method of the chip package structure, and a main difference there between is that in the embodiment, before the step of FIG. 1B, i.e., before forming the solder mask layer 130 on the multi-layer circuit layer 110, a multi-layer power board 150 is formed on the second surface 113 of the multi-layer circuit layer 110 of the second-layer structure with a high coefficient of thermal expansion, where a through hole portion of a bonding film may be filled with a conductive paste after the bonding film is perforated by laser, and then the multi-layer power board 150 may be attached to the multi-layer circuit layer 110 through thermal and pressure bonding to connect to corresponding pads 117 on the multi-layer circuit layer 110. The multi-layer power board 150 includes multi-layer copper and dielectric layers 152 and has a plurality of conductive vias 155. The conductive vias 155 are electrically connected to the multi-layer circuit layer 110 to achieve power transmission. The third group of the structure of the multi-layer power board 150 corresponds to the first-layer structure of the chip 120, which also has a low coefficient of thermal expansion, and sandwich the high coefficient of thermal expansion of the multi-layer circuit layer 110 middle group to maintain a stable balance effect even in a temperature range difference change. Namely, the multi-layer power board 150 of the embodiment does not have a trace structure, but only has split power planes and conductive vias 155 for transmitting power and electrical signals.

Furthermore, in the embodiment, the conductive vias 155 of the multi-layer power board 150 are disposed in the dielectric layer 152 and are electrically connected to each other. In an embodiment, the conductive vias 155 of the multi-layer power board 150 may be arranged in the dielectric layer 152 along a straight line L, but the invention is not limited thereto. In an embodiment, a material of the dielectric layer 152 is, for example, prepreg (PP) or other materials with low coefficient of thermal expansion (CTE). The low coefficient of thermal expansion is, for example, a coefficient of thermal expansion between 1 ppm/K and 3 ppm/K, but the invention is not limited thereto. A material of the conductive via 155 is, for example, copper, but the invention is not limited thereto. Preferably, a first peripheral surface S1 of the multi-layer circuit layer 110 is aligned with a second peripheral surface S2 of the multi-layer power board 150. Namely, dimensions of the multi-layer power board 150 of the embodiment are the same as the dimensions of the multi-layer circuit layer 110. The dimensions may include length, width and/or area. In an embodiment, the multi-layer circuit layer 110 and the multi-layer power board 150 may be regarded as a coreless substrate.

Then, referring to FIG. 2A again, a solder mask layer 160 is formed on the multi-layer power board 150, where the solder mask layer 160 has a plurality of solder mask openings 162. and the solder mask openings 162 expose a part of the conductive vias 155 to define a plurality of conductive via pads P′.

Then, referring to FIG. 2A and FIG. 2B at the same time, the substrate 10 is removed and the structure is turned upside down to expose the first surface 111 of the multi-layer circuit layer 110.

Finally, referring to FIG. 2B again, at least one chip 120 (two chips 120 are schematically shown) is disposed on the first surface 111 of the multi-layer circuit layer 110, where the chip pads 122 of the chip 120 are electrically connected to the multi-layer circuit layer 110 through the solder balls 140. In an embodiment, the chip 120 may be, for example, a single chip or a multi-chip, where the chip 120 is electrically connected to the multi-layer wiring layer 110 in a flip-chip manner. In addition, in order to be electrically connected to an external circuit, the solder ball 145 may be formed on the conductive via pad P′, where the conductive vi pad P′ may be electrically connected to the external circuit through the solder ball 145. At this point. the fabrication of a chip package structure 100b is completed.

The chip package structure 100b of the embodiment has the multi-layer power board 150, where the multi-layer power board 150 may not only transmit electrical signals and power through the conductive vias 155, but may also choose materials with low coefficients of thermal expansion, so that stress generated after the chip 120 is disposed on the multi-layer circuit layer 110 may be effectively balanced. Namely, in the embodiment, the multi-layer power board 150 having the same size as the multi-layer circuit layer 110 is used to stress balance a board warpage phenomenon caused by disposing the chip 120 on the multi-layer circuit layer 110. In brief, through the arrangement of the multi-layer power board 150, the chip package structure 100b of the embodiment may effectively mitigate the board warpage and increase the structural reliability.

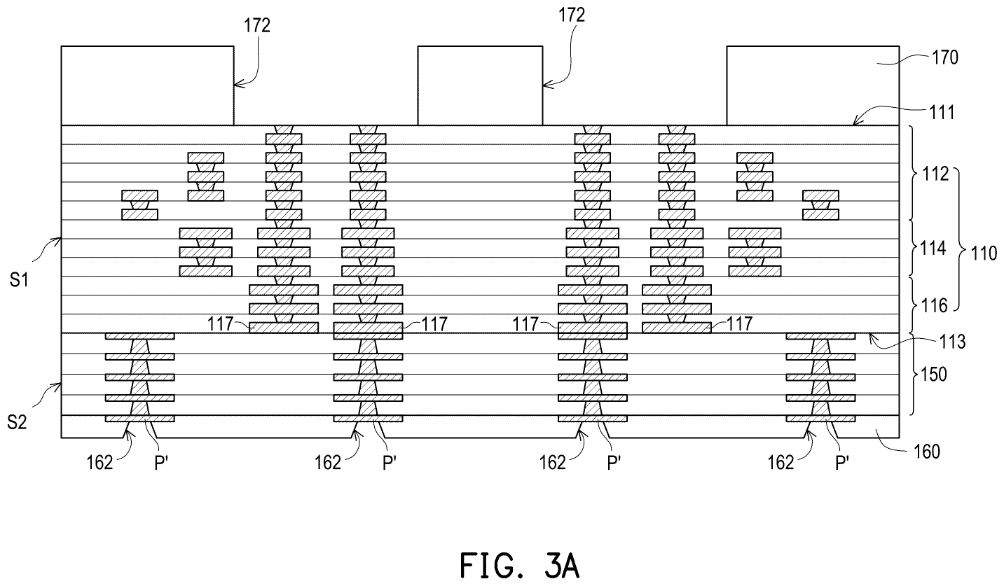

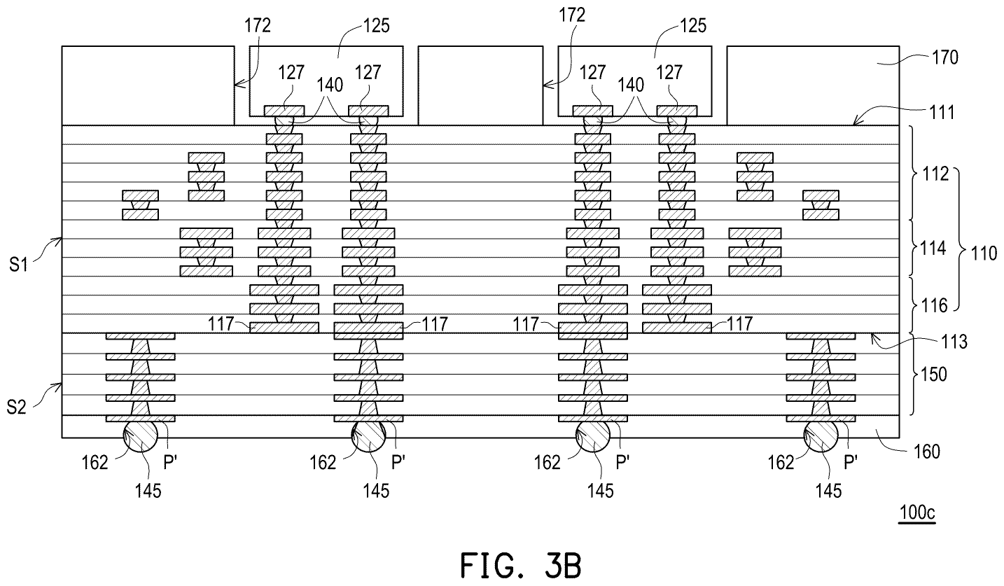

FIG. 3A to FIG. 3B are schematic cross-sectional views of partial steps of a manufacturing method of a chip package structure according to another embodiment of the invention. Referring to FIG. 2A and FIG. 3A at the same time, the manufacturing method of the chip package structure of the embodiment is similar to the aforementioned manufacturing method of the chip package structure, and a main difference there between is that in the embodiment, after the steps of FIG. 2A, i.e., after removing the substrate 10 and flipping the structure upside down to expose the first surface 111 of the multi-layer circuit layer 110, a support plate 170 is disposed on the first surface 111 of the multi-layer circuit layer 110. The support plate 170 has a plurality of openings 172, and chips 125 are respectively disposed in the openings 172. In an embodiment. a material of the support plate 170 is, for example, copper, stainless steel or alloy, but the invention is not limited thereto.

Thereafter, referring to FIG. 3B, a plurality of chips 125 are disposed on the first surface 111 of the high-density circuit layer 112 of the multi-layer circuit layer 110, where the chips 125 are respectively disposed in the openings 172 of the support plate 170, and chip pads 127 of the chips 125 are electrically connected to the multi-layer circuit layer 110 through the solder balls 140. Namely, the chips 125 and the support plate 170 are disposed on a same side and on a same surface (i.e., the first surface 111) of the multi-layer circuit layer 110. Preferably, an orthogonal projection area of the chip 125 on the multi-layer circuit layer 110 plus an orthogonal projection area of the support plate 170 on the multi-layer circuit layer 110 is at least greater than 90% of an area of the multi-layer circuit layer 110, i.e., the area of the support plate 170 may make up for the insufficient area of the chip 125, thereby effectively mitigating the board warpage and increasing structural reliability. At this point, the fabrication of the chip package structure 100c is completed.

In summary, in the chip package structure of the invention, the multi-layer circuit layer with multiple line widths is used to replace the fine circuits and coarse circuits assembled with solder balls in the prior art, thereby eliminating the need for assembly and effectively saving man-hours and material costs.

It will be apparent to those skilled in the art that various modifications and variations can be made to the disclosed embodiments without departing from the scope or spirit of the invention. In view of the foregoing, it is intended that the invention covers modifications and variations provided they fall within the scope of the following claims and their equivalents.

What is claimed is:

1. A chip package structure, comprising:
a multi-layer circuit layer, having a first surface and a second surface opposite to each other, and comprising a high-density circuit layer, a medium-density circuit layer and a low-density circuit layer, the high-density circuit layer having a first surface, the medium-density circuit layer being located between the high-density circuit layer and the low-density circuit layer, the low-density circuit layer having a second surface, wherein the high-density circuit layer has a first line width, the medium-density circuit layer has a second line width, and the low-density circuit layer has a third line width, the first line width is less than the second line width, and the second line width is less than the third line width; and
at least one chip, disposed on the first surface of the high-density circuit layer, and electrically connected to the multi-layer circuit layer.

2. The chip package structure as claimed in claim 1, further comprising:
a multi-layer power board, disposed on the second surface of the multi-layer circuit layer, the multi-layer power board being a circuit substrate with few or no traces and having a plurality of conductive vias, and the conductive vias being electrically connected to the multi-layer circuit layer, wherein a first peripheral surface of the multi-layer circuit layer is aligned with a second peripheral surface of the multi-layer power board.

3. The chip package structure as claimed in claim 2, wherein a coefficient of thermal expansion of the multi-layer power board and a coefficient of thermal expansion of the at least one chip are lower than a coefficient of thermal expansion of the multi-layer circuit layer.

4. The chip package structure as claimed in claim 2, wherein the multi-layer power board comprises dielectric layers, and a coefficient of thermal expansion of each of the dielectric layers is between 1 ppm/K and 3 ppm/K.

5. The chip package structure as claimed in claim 1, further comprising:
a support plate, disposed on the first surface of the multi-layer circuit layer, the support plate having at least one opening, and the at least one chip being disposed in the at least one opening.

6. The chip package structure as claimed in claim 5, wherein a material of the support plate comprises copper, stainless steel or alloy.

7. The chip package structure as claimed in claim 1, wherein a number of layers of the high-density circuit layer ranges from 2 layers to 10 layers, and a line width and line spacing of the high-density circuit layer range from 2 μm to 4 μm.

8. The chip package structure as claimed in claim 1, wherein a number of layers of the medium-density circuit layer ranges from 2 layers to 15 layers, and a line width and line spacing of the medium-density circuit layer range from 5 μm to 10 μm.

9. The chip package structure as claimed in claim 1, wherein a number of layers of the low-density circuit layer ranges from 0 to 20 layers, and a line width of the low-density circuit layer ranges from 10 μm to 20 μm.

10. A manufacturing method of a chip package structure, comprising:
forming a multi-layer circuit layer on a substrate, the multi-layer circuit layer having a first surface and a second surface opposite to each other, and comprising a high-density circuit layer, a medium-density circuit layer and a low-density circuit layer, the high-density circuit layer having a first surface, the medium-density circuit layer being located between the high-density circuit layer and the low-density circuit layer, and the low-density circuit layer having a second surface, wherein the high-density circuit layer has a first line width, the medium-density circuit layer has a second line width, and the low-density circuit layer has a third line width, the first line width is less than the second line width, the second line width is less than the third line width, and the first surface of the multi-layer circuit layer is disposed on the substrate;
removing the substrate to expose the first surface of the multi-layer circuit layer; and
disposing at least one chip on the first surface of the high-density circuit layer, wherein the at least one chip is electrically connected to the multi-layer circuit layer.

11. The manufacturing method of the chip package structure as claimed in claim 10. further comprising:
forming a multi-layer power board on the second surface of the multi-layer circuit layer before removing the substrate to expose the first surface of the multi-layer circuit layer, the multilayer power board being a wireless circuit substrate and having a plurality of conductive vias, and the conductive vias being electrically connected to the multi-layer circuit layer, wherein a first peripheral surface of the multi-layer circuit layer is aligned with a second peripheral surface of the multi-layer power board.

12. The manufacturing method of the chip package structure as claimed in claim 11, wherein a coefficient of thermal expansion of the multi-layer power board and a coefficient of thermal expansion of the at least one chip are lower than a coefficient of thermal expansion of the multi-layer circuit layer.

13. The manufacturing method of the chip package structure as claimed in claim 11. wherein the multi-layer power board comprises dielectric layers, and a coefficient of thermal expansion of each of the dielectric layers is between 1 ppm/K and 3 ppm/K.

14. The manufacturing method of the chip package structure as claimed in claim 10, further comprising:
disposing a support plate on the first surface of the multi-layer circuit layer before disposing the at least one chip on the first surface of the high-density circuit layer, wherein the support plate has at least one opening, and the at least one chip is disposed in the at least one opening.
